(19) United States
(12) Patent Application Publication
(10) Pub. No.: US 2009/0189255 A1
(43) Pub. Date: Jul. 30, 2009

(54) WAFER HAVING HEAT DISSIPATION STRUCTURE AND METHOD OF FABRICATING THE SAME

(75) Inventor: Wei-Min Hsiao, Kaohsiung (TW)

Correspondence Address: J C PATENTS, INC., 4 VENTURE, SUITE 250, IRVINE, CA, 92618, US

(73) Assignee: ADVANCED SEMICONDUCTOR ENGINEERING, INC., Kaohsiung (TW)

(21) Appl. No.: 12/353,663

(22) Filed: Jan. 14, 2009

(30) Foreign Application Priority Data
Jan. 30, 2008 (TW) 97103473

(51) Int. Cl. H01L 29/06; H01L 21/00; H01L 27/00; H01L 23/34; H01L 21/77

(52) U.S. Cl. 257/618; 438/122; 257/E27.001; 257/E21.598

(57) ABSTRACT

A wafer having a heat dissipation structure is provided. The wafer having the heat dissipation structure includes a wafer and a number of metallic heat dissipation parts. The wafer has a first surface and a second surface opposite thereto. Besides, a number of blind holes are formed on the second surface of the wafer. The metallic heat dissipation parts are partially embedded in the blind holes respectively and protrude from the second surface of the wafer.

### CROSS-REFERENCE TO RELATED APPLICATION

This application claims the priority benefit of Taiwan application serial no. 97103473, filed on Jan. 30, 2008. The entirety of the above-mentioned patent application is hereby incorporated by reference herein and made a part of specification.

### BACKGROUND OF THE INVENTION

1. Field of the Invention

The present invention relates to a wafer having a heat dissipation structure and a method of fabricating the same. More particularly, the present invention relates to a wafer having a heat dissipation structure and a method of fabricating the same, in which metallic heat dissipation parts are partially embedded in the wafer.

2. Description of Related Art

Recently, with an unceasing increase in the integration of internal circuitry of integrated circuits (ICs), heat produced by the ICs is also increased continuously. As for personal computers, highly integrated IC chips (such as the IC chips of CPUs or graphic chips) produce a great deal of heat during operation, thus giving rise to an increased system temperature to an undue extent. To allow said IC chips to be operated in a normal manner, the IC chips must be retained under a preferable operating temperature, so as to avoid temporary crash of the system or damage to the system on account of overheating. In other words, with the constant improvement of processing speed and data processing capacity of the IC chips, requirements as to equip outstanding heat dissipation systems have been correspondingly enhanced. Therefore, a heat sink is directly attached to the backside of the IC chips in most cases nowadays, such that the heat generated by the chips during operation can be dissipated by means of the heat sink.

FIG. 1 is a schematic cross-sectional view showing a conventional chip using a heat sink for heat dissipation. According to the related art, a wafer is diced into a number of dies 100 as indicated in FIG. 1, and a thermal adhesive 110 is coated onto a back surface 100b of each of the dies 100. A metallic heat sink 120 is then attached to the back surface 100b of each of the dies 100, such that the heat accumulated on the die 100 is dissipated by the metallic heat sink 120.

Nevertheless, the above-mentioned manner belongs to die-level package. The wafer is required to be diced into the dies in said die level structure, and thereby the heat sink can be respectively attached to the back surface of each of the dies. As such, the complexity arisen from assembling the heat sink to the back surface of each of the dies is raised, and time spent on assembling the heat sink is also increased.

### SUMMARY OF THE INVENTION

The present invention is directed to a wafer having a heat dissipation structure and a method of fabricating the same. In the method, a plurality of metallic heat dissipation parts is directly formed on a second surface of the wafer. The wafer is then diced into a plurality of dies equipped with the metallic heat dissipation parts. Thereby, an issue regarding the increased complexity and time in a conventional process of dicing the wafer into the dies and assembling a heat sink thereto can be resolved.

The present invention provides a wafer having a heat dissipation structure. The wafer having the heat dissipation structure comprises a wafer and a plurality of metallic heat dissipation parts. The wafer has a first surface and a second surface opposite thereto. A plurality of blind holes is formed on the second surface of the wafer. The metallic heat dissipation parts are partially embedded in the blind holes respectively and protrude from the second surface of the wafer.

According to an embodiment of the present invention, the metallic heat dissipation parts are heat dissipation fins or heat dissipation columns.

According to an embodiment of the present invention, the metallic heat dissipation parts are made of copper.

According to an embodiment of the present invention, the first surface can be an active surface. Furthermore, the wafer may comprise a ground pad on the active surface thereof, and one of the metallic heat dissipation parts is connected to the ground pad.

According to an embodiment of the present invention, the wafer having the heat dissipation structure further includes a heat sink attached to the metallic heat dissipation parts.

According to an embodiment of the present invention, the wafer having the heat dissipation structure further includes a thermal adhesive disposed between the heat sink and the metallic heat dissipation parts.

The present invention further provides a method of fabricating a wafer having a heat dissipation structure. The method includes following steps. First of all, a wafer having a first surface and a second surface opposite thereto is provided. Next, a plurality of blind holes is formed on the second surface of the wafer. Thereafter, the blind holes are filled with a metallic material for forming a metallic heat dissipation part in each of the blind holes. Finally, the second surface of the wafer is etched, such that the metallic heat dissipation parts protrude from the second surface of the wafer.

According to an embodiment of the present invention, the step of forming the blind holes on the second surface of the wafer includes performing a dry etching process or a wet etching process on the second surface of the wafer, such that the plurality of blind holes are formed.

According to an embodiment of the present invention, the step of filling the blind holes with the metallic material includes forming the metallic material in the blind holes by an electroplating process.

According to an embodiment of the present invention, the step of etching the second surface of the wafer is performed by a spin etching process on the second surface of the wafer.

According to an embodiment of the present invention, the method of fabricating the wafer having the heat dissipation structure further includes providing a heat sink and attaching the heat sink to the metallic heat dissipation parts.

According to an embodiment of the present invention, the method of fabricating the wafer having the heat dissipation structure further includes performing a wafer bonding process, such that the wafer having the metallic heat dissipation parts is bonded to another wafer. To be more specific, said method further includes dicing the wafer having the metallic heat dissipation parts and another wafer, so as to form a plurality of chips having the heat dissipation structures.

The present invention further provides a method of fabricating a wafer having a heat dissipation structure. The method includes the following steps. First, a wafer having an active surface and a back surface opposite thereto is provided. Wherein, the wafer has a ground pad disposed on the active surface. Next, a plurality of blind holes is formed on the back surfaced of the wafer, and one of the blind holes exposes the ground pad. Thereafter, the blind holes are filled with a metallic material for forming a metallic heat dissipation part in each of the blind holes. Finally, the back surface of the wafer is etched, such that the metallic heat dissipation parts protrude from the back surface of the wafer.

According to an embodiment of the present invention, the step of forming the blind holes on the back surface of the wafer includes performing a dry etching process or a wet etching process on the back surface of the wafer, such that the blind holes are formed.

According to an embodiment of the present invention, the step of filling the blind holes with the metallic material includes forming the metallic material in the blind holes by electroplating.

According to an embodiment of the present invention, the step of etching the back surface of the wafer is performed by a spin etching process on the back surface of the wafer.

According to an embodiment of the present invention, the method of fabricating the wafer further includes providing a heat sink and attaching the heat sink to the metallic heat dissipation parts.

In the method of fabricating the wafer having the heat dissipation structure according to the present invention, the plurality of blind holes is first formed on the second surface of the wafer, and a metallic heat dissipation part is formed in each of the blind holes, such that each of the metallic heat dissipation parts is partially embedded in the wafer. Thereby, the wafer having the heat dissipation structure is formed. Said wafer can be directly diced into the dies, and the metallic heat dissipation parts are embedded in the second surfaces of the dies. As such, the issue regarding the increased complexity and time in the conventional process of cutting the wafer into the dies and then assembling the heat sink thereto is resolved. Moreover, the metallic heat dissipation parts are directly embedded in the wafer, and thus the heat dissipation performance is enhanced.

On the other hand, the method of fabricating the wafer having the metallic heat dissipation parts according to the present invention can be applied to a dummy wafer to serve as a wafer-level heat sink. Said wafer-level heat sink can be directly bonded to another wafer. After that, the wafer is diced to form a plurality of dies having a heat sink on the second surface thereof. Thereby, the process of assembling the dies to the heat sink is expedited.

In order to make the aforementioned and other objects, features and advantages of the present invention more comprehensible, several embodiments accompanied with figures are described in detail below.

### BRIEF DESCRIPTION OF THE DRAWINGS

FIG. 1 is a schematic cross-sectional view showing a conventional chip using a heat sink for heat dissipation.

FIGS. 2A to 2E are schematic cross-sectional views illustrating a process of fabricating a wafer having a heat dissipation structure according to an embodiment of the present invention.

FIG. 3 is a schematic cross-sectional view in which the wafer having the heat dissipation structure as shown in FIG. 2D is bonded to another wafer.

FIGS. 4A to 4D are schematic cross-sectional views depicting a process of fabricating a wafer having a heat dissipation structure according to another embodiment of the present invention.

FIGS. 5A to 5C are schematic cross-sectional views illustrating a process of assembling a wafer-level heat sink to another wafer.

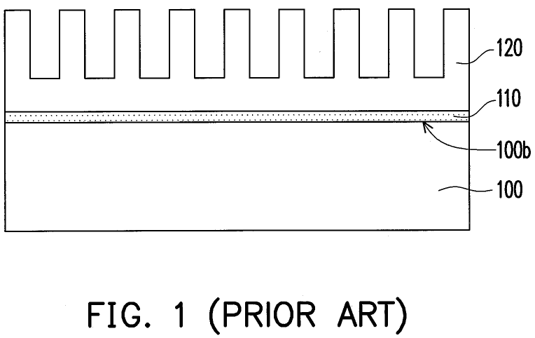

### DESCRIPTION OF EMBODIMENTS

Wafers provided with an active surface capable of performing functions are taken as examples in the following embodiments. However, types of wafer do not limit the scope of the present invention. For instance, dummy wafers without active surfaces can also be adopted in the present invention.

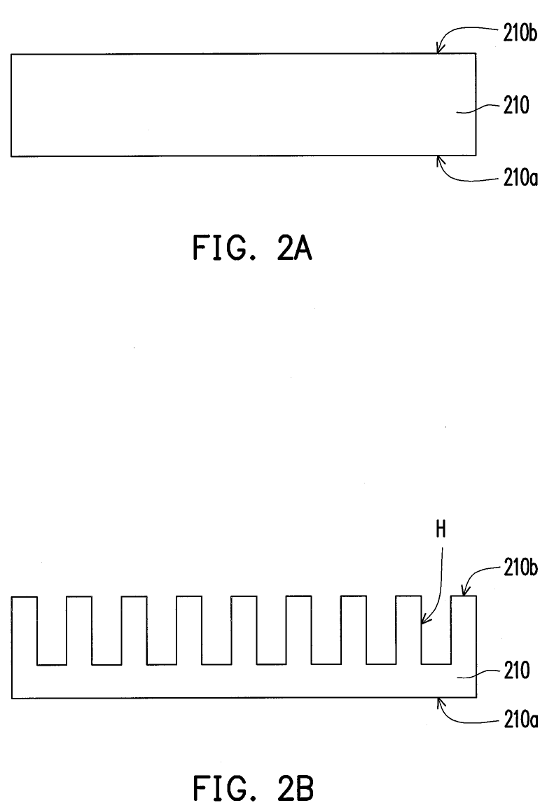

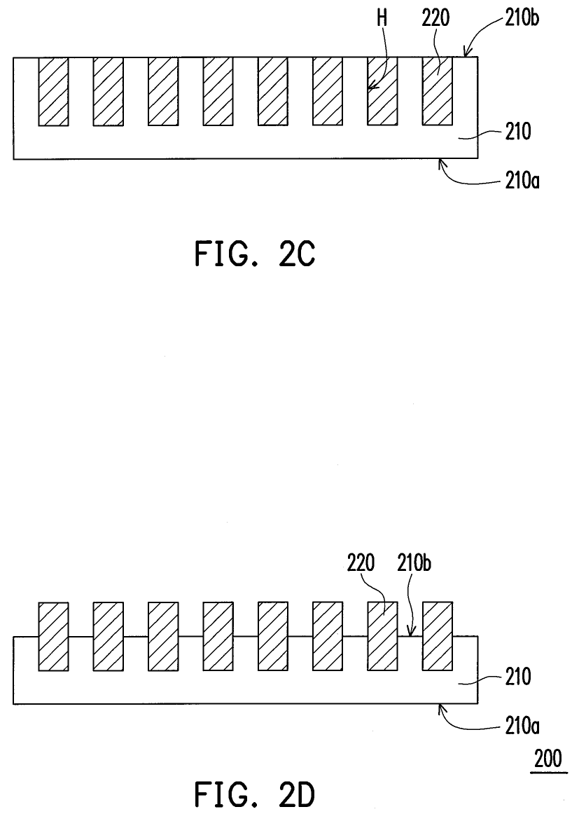

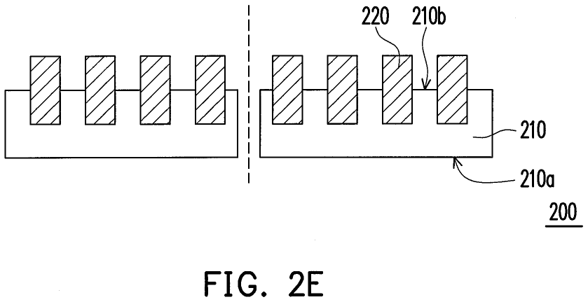

FIGS. 2A to 2E are schematic cross-sectional views illustrating a process of fabricating a wafer having a heat dissipation structure according to an embodiment of the present invention. First, referring to FIG. 2A, a wafer 210 having an active surface 210a and a back surface 210b opposite thereto is provided. Next, as indicated in FIG. 2B, a plurality of blind holes H is formed on the back surface 210b of the wafer 210. In this step, a dry etching process or a wet etching process can be performed on the back surface 210b of the wafer 210, so as to form the blind holes H. The shape of the blind holes H may influence the shape of metallic heat dissipation parts subsequently formed on the back surface 210b of the wafer 210. Hence, the blind holes H may be designed to have a sheet structure or a column structure based on actual requirement, so as to form metallic heat dissipation fins or metallic heat dissipation columns.

Thereafter, referring to FIG. 2C, the blind holes H formed on the back surface 210b of the wafer 210 are filled with a metallic material for forming a metallic heat dissipation part 220 in each of the blind holes H. In one embodiment of the present invention, the blind holes H can be filled with the metallic material by electroplating or adopting other appropriate methods. Additionally, the appropriate metallic material includes copper or other metallic materials characterized by outstanding thermal conductivity.

Finally, referring to FIG. 2D, the back surface 210b of the wafer 210 is etched, such that the metallic heat dissipation parts 220 protrude from the back surface 210b of the wafer 210. In this step, a spin etching process capable of achieving favorable etching uniformity can be utilized for etching the back surface 210b of the wafer 210, and the metallic heat dissipation parts 220 formed thereby are of a satisfactory shape. The shape of the metallic heat dissipation parts 220 varies upon the shape of the blind holes H. For example, the metallic heat dissipation parts 220 may be the heat dissipation fins or the heat dissipation columns. The shape of the metallic heat dissipation parts 220 is not limited in the present invention. So far, the fundamental process of fabricating a wafer 200 having the heat dissipation structure according to the present invention is completed. After the completion of said fabrication process, the wafer 200 can be diced into a number of dies, such that each of the dies has the metallic heat dissipation parts 220 on the back surface thereof. As such, an issue regarding an increased complexity and time in a conventional process of cutting the wafer into the dies and then assembling a heat sink thereto is resolved.

As shown in FIG. 2D, the wafer 200 having the heat dissipation structure and formed by performing said fabricating process mainly includes a wafer 210 and a plurality of metallic heat dissipation parts 220. The wafer 210 has an active surface 210a and a back surface 210b opposite thereto. A plurality of blind holes H is formed on the back surface 210b of the wafer 210. The metallic heat dissipation parts 220 are partially embedded in the blind holes H respectively and protrude from the back surface 210b of the wafer 210. Wherein, the metallic heat dissipation parts 220 can be the heat dissipation fins or the heat dissipation columns. Furthermore, the shape of the metallic heat dissipation parts 220 is not limited in the present invention.

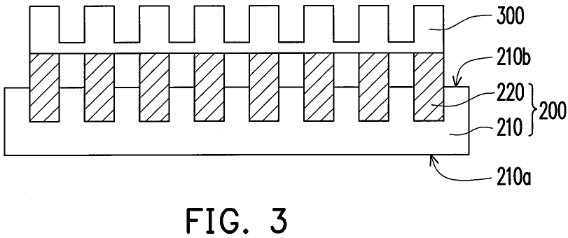

In addition, after the step indicated in FIG. 2D is completely carried out, a heat sink 300 can be additionally provided as illustrated in FIG. 3, and the heat sink 300 is attached to the metallic heat dissipation parts 220 for further improving the heat dissipation efficacy of the wafer 200. Moreover, a thermal adhesive (not shown) can be alternatively placed between the metallic heat dissipation parts 220 and the heat sink 300, such that heat can be conducted to the heat sink 300 in a more effective manner.

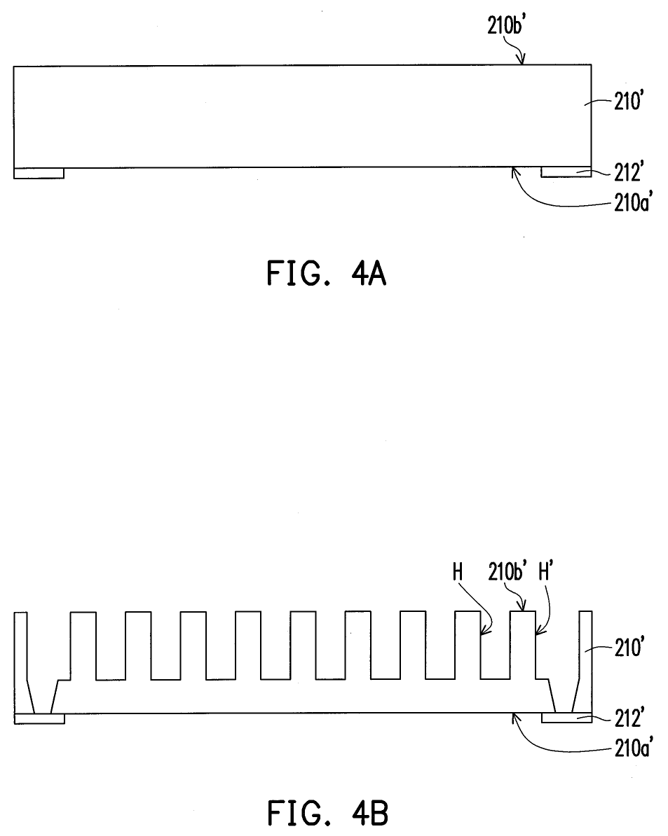

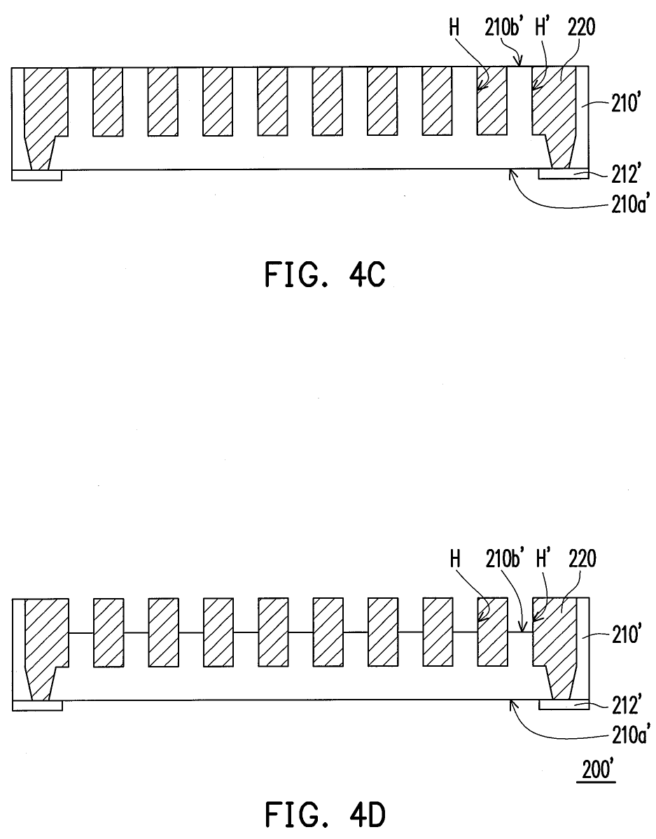

FIGS. 4A to 4D are schematic cross-sectional views depicting a process of fabricating a wafer having a heat dissipation structure according to another embodiment of the present invention. First, as shown in FIG. 4A, a wafer 210′ and the wafer 210 shown in FIG. 2A are approximately the same, while the difference therebetween lies in that a ground pad 212′ is further formed on an active surface 210a′ of the wafer 210′. Next, as indicated in FIG. 4B, a plurality of blind holes H is formed on a back surface 210b′ of the wafer 210′. In this step, the dry etching process or the wet etching process can be performed to etch the back surface 210b′ of the wafer 210′, so as to form the blind holes H. Besides, blind holes H′ corresponding to the ground pad 212′ pass through the wafer 210′, so as to expose the ground pad 212′.

Thereafter, referring to FIG. 4C, the blind holes H on the back surface 210b of the wafer 210′ are filled with a metallic material for respectively forming one metallic heat dissipation part 220 in each of the blind holes H and the blind holes H′. Finally, referring to FIG. 4D, the back surface 210b′ of the wafer 210′ is etched, such that the metallic heat dissipation parts 220 protrude from the back surface 210b′ of the wafer 210′. Here, the metallic heat dissipation parts 220 formed on the ground pad 212′ are grounded. The fabrication of a wafer 200′ having the heat dissipation structure according to the present invention is so far completed. Since the manufacturing process of the wafer 200′ having the heat dissipation structure as provided in FIGS. 4A to 4D is similar to that described in FIGS. 2A to 2D, no further detailed description in this regard is given hereinafter.

Moreover, the process of fabricating the wafer having the heat dissipation structure not only can be applied to the wafer on the active surface of which the components are already formed, but also can be applied to normal wafers, such that the wafer fabricated by performing said process can serve as a wafer-level heat sink.

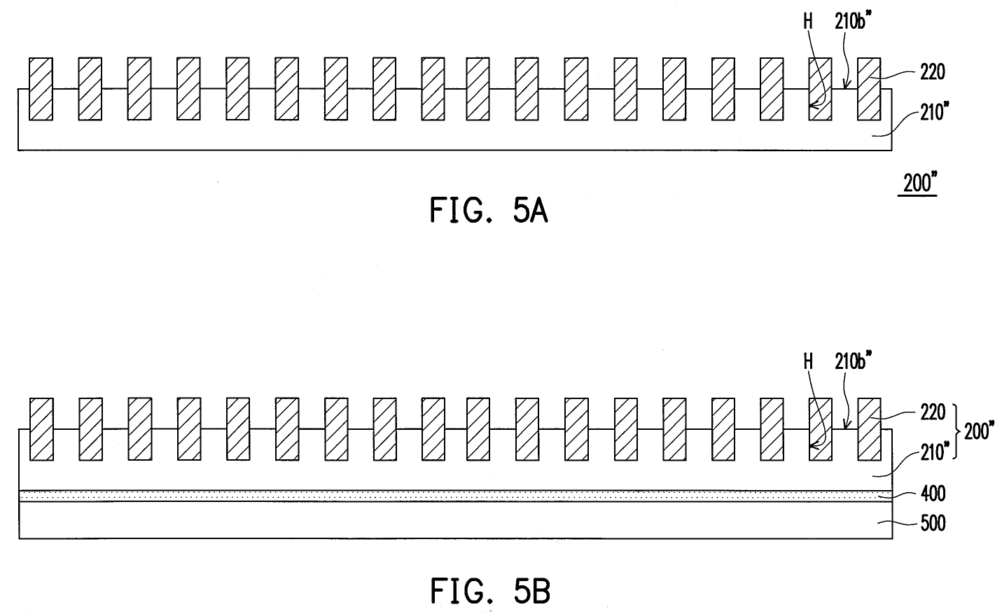

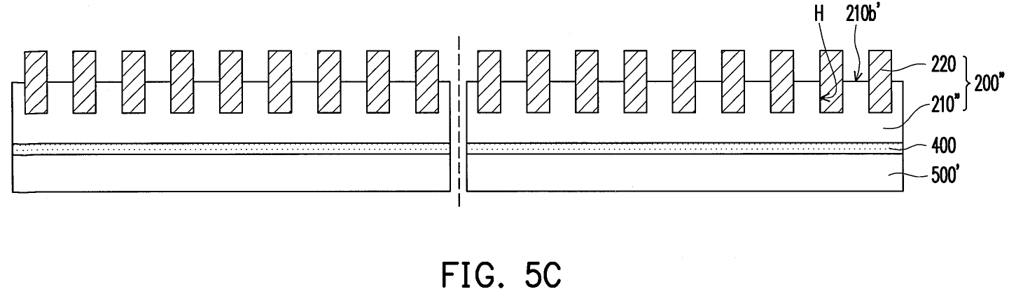

FIGS. 5A through 5C are schematic cross-sectional views depicting a process of assembling a wafer to another wafer-level heat sink. First, referring to FIG. 5A, a wafer-level heat sink 200″ fabricated by the steps described in FIGS. 2A through 2D is provided. The wafer-level heat sink 200″ is composed of a wafer 210″ and a plurality of metallic heat dissipation parts 220 partially embedded in the blind holes H on a back surface 210b″ of the wafer 210″. The wafer 210″ is a dummy wafer without any devices on a surface thereof. Next, referring to FIG. 5B, a wafer bonding process is performed to bond the wafer-level heat sink 200″ to a wafer 500 having devices on a surface thereof. In one embodiment of the present invention, a thermal adhesive 400 can be placed between the wafer 500 and the wafer-level heat sink 200″ for conducting heat. Finally, referring to FIG. 5C, after said fabrication process is completed, the wafer 210″ can then be diced into a number of dies 500′, and each of the dies 500′ has a heat sink on the back surface thereof.

In the method of fabricating the wafer having the heat dissipation structure according to the present invention, the plurality of blind holes is first formed on the back surface of the wafer, and one metallic heat dissipation part is formed in each of the blind holes, such that each of the metallic heat dissipation parts is partially embedded in the wafer. Thereby, the wafer having the heat dissipation structure is formed. Said wafer can be directly diced for forming the dies with the metallic heat dissipation parts embedded in the back surfaces thereof. As such, the issue regarding the increased complexity and time in the conventional process of dicing the wafer into the dies and then assembling the heat sink thereto is resolved. Moreover, the metallic heat dissipation parts are directly embedded in the wafer, and thus the heat dissipation performance can be enhanced.

On the other hand, the method of fabricating the wafer having the metallic heat dissipation parts according to the present invention can be applied to a dummy wafer, to serve as a wafer-level heat sink. Said wafer-level heat sink can be directly bonded to other wafers. After that, the wafer is diced for forming the dies with the heat sink on the back surfaces thereof. Thereby, the process of assembling the dies to the heat sink is also expedited.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A wafer having a heat dissipation structure, comprising:
a wafer, having a first surface and a second surface opposite thereto, wherein the second surface of the wafer has a plurality of blind holes; and
a plurality of metallic heat dissipation parts, partially embedded in the blind holes respectively and protruding from the second surface of the wafer.

2. The wafer having the heat dissipation structure as claimed in claim 1, wherein the metallic heat dissipation parts are heat dissipation fins or heat dissipation columns.

3. The wafer having the heat dissipation structure as claimed in claim 1, wherein the metallic heat dissipation parts are made of copper.

4. The wafer having the heat dissipation structure as claimed in claim 1, wherein the first surface is an active surface.

5. The wafer having the heat dissipation structure as claimed in claim 4, wherein the active surface of the wafer further comprises a ground pad formed thereon, and one of the metallic heat dissipation parts is connected to the ground pad.

6. The wafer having the heat dissipation structure as claimed in claim 1, further comprising a heat sink attached to the metallic heat dissipation parts.

7. The wafer having the heat dissipation structure as claimed in claim 6, further comprising a thermal adhesive disposed between the heat sink and the metallic heat dissipation parts.

8. A method of fabricating a wafer having a heat dissipation structure, the method comprising:
providing a wafer having a first surface and a second surface opposite thereto;
forming a plurality of blind holes on the second surface of the wafer;
filling the blind holes with a metallic material for forming a metallic heat dissipation part in each of the blind holes; and
etching the second surface of the wafer, such that the metallic heat dissipation parts protrude from the second surface of the wafer.

9. The method of fabricating the wafer having the heat dissipation structure as claimed in claim 8, wherein the step of forming the blind holes on the second surface of the wafer is performed by a dry etching process or a wet etching process on the second surface of the wafer to form the blind holes.

10. The method of fabricating the wafer having the heat dissipation structure as claimed in claim 8, wherein the step of filling the blind holes with the metallic material is performed by an electroplating process.

11. The method of fabricating the wafer having the heat dissipation structure as claimed in claim 8, wherein the step of etching the second surface of the wafer is performed by a spin etching process on the second surface of the wafer.

12. The method of fabricating the wafer having the heat dissipation structure as claimed in claim 8, further comprising providing a heat sink and attaching the heat sink to the metallic heat dissipation parts.

13. The method of fabricating the wafer having the heat dissipation structure as claimed in claim 8, further comprising performing a wafer bonding process, such that the wafer having the metallic heat dissipation parts is bonded to another wafer.

14. The method of fabricating the wafer having the heat dissipation structure as claimed in claim 12, further comprising dicing the wafer having the metallic heat dissipation parts and another wafer, so as to form a plurality of chips having the heat dissipation structure.

15. A method of fabricating a wafer having a heat dissipation structure, the method comprising:
providing a wafer having an active surface and a back surface opposite thereto, wherein the wafer has a ground pad formed on the active surface;
forming a plurality of blind holes on the back surface of the wafer, wherein one of the blind holes exposes the ground pad;
filling the blind holes with a metallic material for forming a metallic heat dissipation part in each of the blind holes; and
etching the back surface of the wafer, such that the metallic heat dissipation parts protrude from the back surface of the wafer.

16. The method of fabricating the wafer having the heat dissipation structure as claimed in claim 14, wherein the step of forming the blind holes on the back surface of the wafer is performed by a dry etching process or a wet etching process on the back surface of the wafer to form the blind holes.

17. The method of fabricating the wafer having the heat dissipation structure as claimed in claim 14, wherein the step of filling the blind holes with the metallic material is performed by an electroplating process.

18. The method of fabricating the wafer having the heat dissipation structure as claimed in claim 14, wherein the step of etching the back surface of the wafer is performed by a spin etching process on the back surface of the wafer.

19. The method of fabricating the wafer having the heat dissipation structure as claimed in claim 14, further comprising providing a heat sink and attaching the heat sink to the metallic heat dissipation parts.
